(19) United States
(12) Patent Application Publication
(10) Pub. No.: US 2021/0194464 A1
(43) Pub. Date: Jun. 24, 2021

(54) FRI SPARSE SAMPLING KERNEL FUNCTION CONSTRUCTION METHOD AND CIRCUIT

(71) Applicant: JIANGSU UNIVERSITY, Jiangsu (CN)

(72) Inventors: Shoupeng SONG, Jiangsu (CN); Zhou JIANG, Jiangsu (CN)

(21) Appl. No.: 16/070,949

(22) PCT Filed: Jun. 16, 2017
(86) PCT No.: PCT/CN2017/088676

§ 371 Date: Jul. 18, 2018

(30) Foreign Application Priority Data
Jun. 8, 2017 (CN) 201710425270.0

(51) Int. Cl. H03H 17/02; G06F 17/14

(52) U.S. Cl. CPC H03H 17/0213; G06F 17/14

(57) ABSTRACT

The invention discloses an FRI sparse sampling kernel function construction method and a circuit. According to the characteristics of an analog input signal and a subsequent parameter estimation algorithm, the method determines the criteria to be satisfied by the sampling kernel, designs a frequency response function of a Fourier series coefficient screening circuit, determines performance parameters of the frequency response function for the sampling kernel, and obtains a sampling kernel function after correction. The circuit is implemented with a Fourier series coefficient screening module and a phase correction module that are connected in cascade. The Fourier series coefficient screening module uses a Chebyshev II low-pass filtering circuit, and the phase correction module uses an all-pass filter circuit. Signals can be directly sparsely sampled according to the rate of innovation of the signals after passing through the sampling kernel circuit, and original characteristic parameters of the signals can be accurately recovered by a parameter estimation algorithm after sparse data is obtained. The FRI sparse sampling kernel provided in the invention is particularly suitable for an FRI sparse sampling system for pulse stream signals, the sampling rate is much lower than a conventional Nyquist sampling rate, and the data acquisition quantity is greatly decreased.

### TECHNICAL FIELD

The present invention belongs to the technical field of signal sparse sampling, in particular to a FRI sparse sampling kernel function construction method for pulse stream signals and a hardware circuit implementation.

### BACKGROUND ART

The Finite Rate of Innovation (FRI) sampling theory is a new method of sparse sampling, proposed by Vetterli et al. in 2002. According to the sampling theory, sparse sampling for FRI signals can be carried out at a rate much lower than the Nyquist sampling frequency, and the original signal can be reconstructed accurately. In the initial stage after the method was proposed, the method theoretically solved sparse sampling problems of non-band-limited signals, including Dirac stream signals, differential Dirac stream signals, non-uniform spline signals, and piecewise polynomial signals, i.e., the signals is sparsely sampled according to the rate of innovation of the signals, then the amplitude and time delay parameters of the signals are estimated by the spectral analysis algorithm, and finally the time domain waveforms of the signals can be reconstructed with those parameters. After development for almost 15 years, the FRI sampling theory has been applied in many fields such as ultra-wideband communication, GPS, radar, medical ultrasonic imaging and industrial ultrasonic detecting, etc. At present, FRI sampling is still in a theoretical research stage. Among the research results, a sparse data acquisition method is to perform conventional sampling of samples, then carry out the double sampling of the signals by the digital signal processing algorithm, and finally obtain the FRI sparsely sampled data. The applied research of the FRI sampling theory in various fields is also based on simulation, and sparsely sampled data cannot be obtained truly from hardware. Therefore, to truly apply the FRI sparse sampling theory in practical applications, it is necessary to physically implement the FRI sampling theory. One of the key challenges in the physical implementation of the FRI sampling theory is the hardware implementation of a sampling kernel.

In FRI sampling, the function of a sampling kernel is to transform signals into a form of power series weighted sum. For pulse stream signals, the amplitude is contained in the weight, and the time delay information of signal is contained in the power series. The power series can be solved with a spectral estimation method, thereby the time delay information can be obtained, and then the amplitude information may be obtained. The existing sampling kernels may be divided into two categories generally, according to the approach in which the signals are transformed into the form of a power series weighted sum. The first category of methods is to acquire Fourier series coefficients of the signals, and utilize the Fourier series coefficients in a special form (having the form of power series weighted sum) to carry out parameter estimation in the frequency domain. Existing sine kernels and SoS (Sum of Sinc) kernels, etc. all belong to this category. The second category of methods is to convolute the signal with a kernel function in the time domain to construct a form of a power series weighted sum, and then carry out the parameter estimation. This category mainly includes Gaussian kernels and regenerative sampling kernels (polynomial regeneration and exponential regeneration). However, most existing sampling kernel functions are intended to provide mathematical convenience, and there is no detail description on the hardware implementation. The Eldar team put forth a multi-channel FRI sampling hardware implementation method in an article “Multichannel Sampling of Pulse Streams at the Rate of Innovation”, IEEE Transactions on Signal Processing, 2011, 59(2): 1491-1504. In the method, the number of system channels is proportional to the number of unknown parameters to be detected. In the case of a large number of unknown parameters, the complexity of the hardware system is too large to satisfy actual FRI sampling. In an article “Sub-Nyquist Radar Prototype: Hardware and Algorithms”, IEEE Transactions on Aerospace and Electronic Systems, 2014, 50(2): 809-822, for radar signals, a sampling kernel is constructed with a high-Q crystal band filter, and a four-channel pulse receiver is designed; thus, FRI sampling for radar signals is implemented in hardware for the first time, and the four-channel pulse receiver is applied to sparse sampling of ultrasonic signals. Though the pulse receiver can sparsely sample the radar signals and ultrasonic signals at a rate lower than the conventional Nyquist sampling rate, the sampling rate is still much higher than the actual rate of innovation of the signals, i.e., sampling at the rate of innovation is not realized truly.

According to data retrieval, there is currently no hardware FRI sampling system that can be applied practically and has a sampling rate that satisfies the criterion of rate of innovation. The problem of physical implementation of a sampling kernel must be solved radically, in order to enable FRI sparse sampling methods to be applied truly and practically. The present invention provides a FRI sparse sampling kernel function construction method and a hardware implementation for pulse stream signals.

### CONTENT OF THE INVENTION

In view that there is no physical implementation of a FRI sparse sampling kernel for pulse stream signals yet, the present invention provides a physical implementation method and a circuit. The circuit utilizes a Chebyshev II low-pass filter link and an all-pass filter link to constitute a sampling kernel, Fourier series coefficients of a signal can be obtained with a digital signal processing algorithm from sparsely sampled data after sampling kernel, and thereby the original signal can be reconstructed. The method has advantages of simple hardware structure, easy implementation and less data acquisition, etc.

The specific steps for implementing the present invention are as follows:

A FRI sparse sampling kernel function construction method comprises the following steps:

Step 1: determining the number and distribution intervals of the Fourier series coefficients required for accurately estimating signal parameters from sparsely sampled data, according to the characteristics of the FRI pulse stream signal and the parameters to be estimated subsequently; the characteristics of the pulse stream signal refer to that there are a limited number of pulse signals in a limited timer, and the limited time T may be extended to a signal with a period T; the parameters to be estimated subsequently refer to the time delay and amplitude of the pulses.

Step 2: obtaining amplitude-frequency criteria that must be satisfied by frequency domain response of a sampling kernel, according to the number and the distribution intervals of the Fourier series coefficients required for parameter estimation in the step 1.

Step 3: designing a frequency response function for a Fourier series coefficient screening circuit and determining performance parameters of the frequency response function of the sampling kernel, according to the amplitude-frequency criteria for the sampling kernel in the step 2, wherein, the parameters mainly include: pass-band cut-off frequency, stop-band cut-off frequency, maximum pass-band attenuation coefficient and minimum stop-band attenuation coefficient.

Step 4: utilizing a phase correction module to phase correct the transfer function, and thereby obtaining a corrected transfer function of the sampling kernel, i.e., a final sampling kernel function, in order to improve stability of response of the Fourier series coefficient screening circuit and accuracy of parameter estimation, according to the characteristics of phase nonlinearity of the frequency response function for the Fourier series coefficient screening circuit determined in the step 3.

Furthermore, the FRI pulse stream signal described in the step 1 can be extended into a periodic pulse stream signal by the following expression:

$$x ( t ) = {\sum }_{m ∈ Z} {\sum }_{l = 0}^{L - 1} {a}_{l} h ( t - {t}_{l} - m τ )$$

Where, tₗ∈[0, τ), aₗ∈C, l=1, . . . , L, τ is the period of signal x(t), L is the number of pulses in a single period, h(t) is a pulse in a known shape; m is an integer, and Z is the set of integers.

Furthermore, the Fourier series coefficients are determined as

$$X [ \frac{2 π k}{τ} ] ,$$

k∈{−L, . . . , L}, according to the period τ of the FRI pulse stream signal and the number of pulses L in a single period in the Step 1, with an annihilating filter parameter estimation method.

Furthermore, according to the Fourier series coefficients required for reconstruction in the Step 1, the frequency domain response of the sampling kernel must satisfy the following criteria:

$$\vert S ( f ) \vert = \{ \begin{matrix}0 & f = \frac{k}{τ} , k ∉ K \\ not zero & f = \frac{k}{τ} , k ∈ K \\ arbitrary value & others\end{matrix}$$

Wherein, S(f) is the frequency domain response of the sampling kernel, K={−L, . . . , L}.

Furthermore, according to the criteria for the sampling kernel, the sampling kernel parameters based on the frequency response function for the Fourier series coefficient screening circuit must satisfy the following criteria:

$$\{ \begin{matrix}{f}_{p} \geq \frac{L}{τ} \\ {f}_{s} \leq \frac{L + 1}{τ} \\ \vert S ( f ) \vert \neq 0 , f \leq {f}_{p} \\ \vert S ( f ) \vert = 0 , f \geq {f}_{p}\end{matrix}$$

Wherein, fₚ is pass-band cut-off frequency, and fₛ is stop-band cut-off frequency.

Through further optimization of the sampling kernel parameters, values of the pass-band cut-off frequency fₚ and stop-band cut-off frequency fₛ are as follows respectively:

$$\{ \begin{matrix}{f}_{p} = \frac{2 L}{τ} \\ {f}_{s} = \frac{2 L + 1}{τ}\end{matrix}$$

The maximum pass-band attenuation aₚ and minimum stop-band attenuation aₛ of the sampling kernel can be determined according to the requirement for the accuracy of signal reconstruction and the difficulty in the physical implementation of the sampling kernel.

The present invention provides a hardware implementation circuit of FRI sparse sampling kernel, comprising a Fourier series coefficient screening module and a phase correction module.

The Fourier series coefficient screening module uses a Chebyshev II low-pass filter circuit and the phase correction module uses an all-pass filter circuit; the Fourier series coefficient screening circuit module and the phase correction module are connected in series.

Fourier series coefficients required for parameter estimation can be obtained after the analog pulse stream signal passes through the Fourier series coefficient screening module; the phase correction module is configured to compensate the nonlinear phase of the Fourier series coefficient screening module, so that the phase in a pass band is approximately linear.

The present invention attains the following beneficial effects:

FRI sparsely sampled data of pulse stream signals is directly obtained with hardware circuits, different from the existing approach in which sparse data is obtained by double sampling the digital signals again; in addition, the sampling frequency matches the rate of is innovation of signals, and much lower than the conventional Nyquist frequency. Besides, the hardware circuit of sampling kernel provided in the present invention has advantages of simple structure and easy implementation. When the hardware circuit is applied to the sampling of pulse stream signals, the signal sampling rate and data acquisition quantity can be decreased greatly.

### DESCRIPTION OF DRAWINGS

FIG. 1 is a functional block diagram of the system for sparse sampling and parameter estimation of pulse stream signals according to an embodiment of the present invention.

FIG. 2 is a schematic circuit diagram of the Fourier series coefficient screening module according to an embodiment of the present invention.

FIG. 3 is a schematic circuit diagram of the phase correction module according to an embodiment of the present invention.

FIG. 4 shows the time and frequency domain response curves of the 7-order Chebyshev II low-pass filter according to an embodiment of the present invention. (4a) is the unit pulse response curve; (4b) is the amplitude-frequency curve.

FIG. 5 shows the time and frequency domain response curves of the sampling kernel designed according to an embodiment of the present invention. (5a) is the unit pulse response curve; (5b) is the amplitude-frequency curve.

FIG. 6 shows the time and frequency domain response curves of an existing SoS sampling kernel. (6a) is the unit pulse response curve; (6b) is the amplitude-frequency curve.

FIG. 7 shows the experimental results of a simulated signal according to an embodiment of the present invention. (7a) is the experimental result of the sampling kernel designed in the present invention; (7b) is the experimental result of a SoS sampling kernel.

FIG. 8 shows the experimental results of an actually measured signal according to an embodiment of the present invention. (8a) is the experimental result of the sampling kernel designed in the present invention; (8b) is the experimental result of a SoS sampling kernel

### EMBODIMENTS

Hereunder the technical scheme of the present invention will be further described with reference to the accompanying drawings and embodiments.

Assume that the periodic pulse stream signal is:

$$x ( t ) = {\sum }_{m ∈ Z} {\sum }_{l = 0}^{L - 1} {a}_{l} h ( t - {t}_{l} - m τ )$$

Where, tₗ is the time delay of pulses, aₗ is the amplitude of the pulses, τ is the period of signal x(t), L is the number of pulses in a single period, h(t) is a pulse in a known shape; m is an integer, and Z is the set of integers.

The required Fourier series coefficients are determined as

$$X [ \frac{2 π k}{τ} ] ,$$

k∈{−L, . . . , L}, according to the period τ of the analog input FRI signal and the number of echoes L in a single period, with an annihilating filter parameter estimation method.

According to the Fourier series coefficients required for parameter estimation, the frequency domain response of the sampling kernel must satisfy the following criteria:

$$\vert S ( f ) \vert = \{ \begin{matrix}0 & f = \frac{k}{τ} , k ∉ K \\ not zero & f = \frac{k}{τ} , k ∈ K \\ arbitrary value & others\end{matrix}$$

Wherein, S(f) is the frequency domain response of the sampling kernel, K={−L, . . . , L}.

According to the sampling kernel criteria, the parameters of the Chebyshev II low-pass filter sampling kernel must satisfy the following criteria:

$$\{ \begin{matrix}{f}_{p} \geq \frac{L}{τ} \\ {f}_{s} \leq \frac{L + 1}{τ} \\ \vert S ( f ) \vert \neq 0 , f \leq {f}_{p} \\ \vert S ( f ) \vert = 0 , f \geq {f}_{p}\end{matrix}$$

Wherein, fₚ is pass-band cut-off frequency, and fₛ is stop-band cut-off frequency.

To minimize the number of orders of the designed sampling kernel, the values of the pass-band cut-off frequency fₚ and stop-band cut-off frequency fₛ of the sampling kernel are as follows respectively:

$$\{ \begin{matrix}{f}_{p} = \frac{2 L}{τ} \\ {f}_{s} = \frac{2 L + 1}{τ}\end{matrix}$$

According to the criteria for the parameters of the Chebyshev II low-pass filtering sampling kernel, the amplitude of the sampling kernel must not be zero in the pass band, and must be zero in the stop band. In practice, it is very difficult for a low-pass filter function which can be implemented physically to achieve a strict zero amplitude in the stop-band. In view of that, the stop-band attenuation coefficient should be set to be high enough, so that the stop-band amplitude is approximately zero. Here, the pass-band amplitude and stop-band amplitude of the sampling kernel are adjusted by means of two parameters: maximum pass-band attenuation aₚ and minimum stop-band attenuation aₛ. The smaller the aₚ is and the greater the aₛ is, the better the sampling kernel reconstruction effect is, but the higher the number of orders of the filter is, the more complex the circuit is.

To improve the accuracy of the obtained Fourier series coefficients, a Chebyshev II low-pass filter function is used as the sampling kernel, and a subsequent phase correction link is added, so that the phase of the sampling kernel function in the pass band is approximately linear.

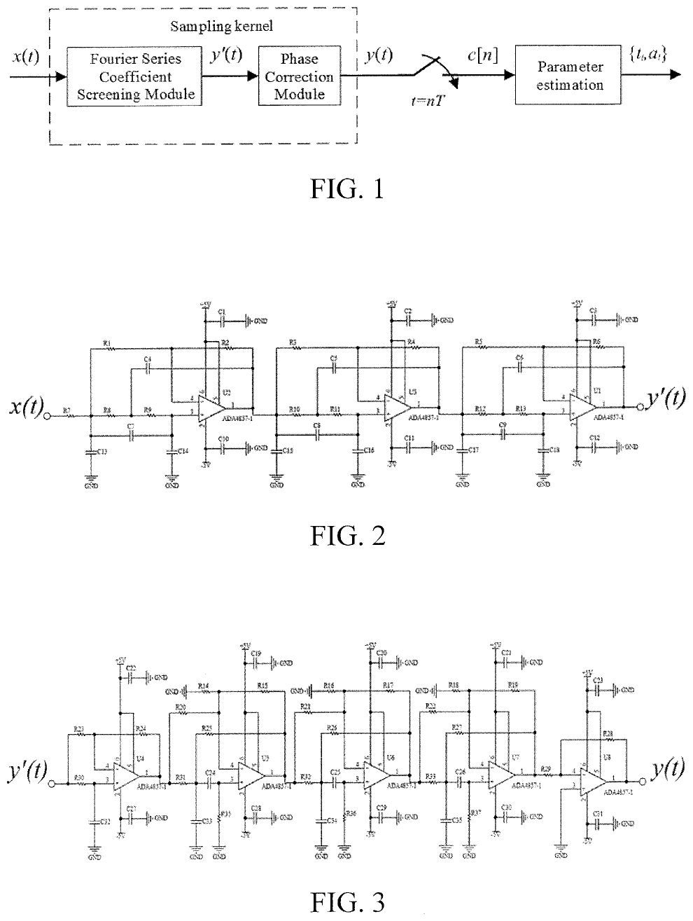

As shown in FIG. 1, the hardware circuit of FRI sparse sampling kernel provided in the present invention comprises a Fourier series coefficient screening module and a phase correction module; unnecessary Fourier series coefficients are removed when the analog input signal passes through the Fourier series coefficient screening module, and the phase correction module compensates the nonlinear phase of the Fourier series coefficient screening module, so that the phase in the pass band is approximately linear; the Fourier series coefficient screening module and the phase correction module are connected in series.

The Fourier series coefficient screening module, based on a basic active low-pass filter link in a Sallen-key structure, is implemented by three-stage operational amplifier circuits cascade, and the active low-pass filter link is a 7-order link composed of five-stage high-speed operational amplifiers ADA4857 and a resistance-capacitance network that are connected in cascade, as shown in FIG. 2.

The phase correction module is implemented by an active all-pass filter link which is composed of high-speed operational amplifiers ADA4857 and a resistance-capacitance network, as shown in FIG. 3.

Hereunder the effects of the present inventions will be further described by the following simulation experiment:

The simulation parameters are as follows:

The periodic pulse stream signal is x(t)=Σ_{m∈Z}Σᵢ₌₀^{L-1}aₗh(t−tₗ−mτ), wherein, h(t) is a Gaussian pulse and the expression is h(t)=e^{-αt}^{²}, α is the bandwidth factor of the Gaussian pulse. The signal period is τ=10 μs, the number of pulses is L=3, the number of sampling points is 1001, the bandwidth factor of the Gaussian pulse is α=(2.5 MHz)², the pulse amplitudes are (1,0.3,0.8) respectively, the pulse time delays are (2 μs, 5 μs, 8 μs) respectively. The number of sampling points for the sparse sampling is set to 7 according to the number of pulses.

According to the pulse stream signal, the parameters of the sampling kernel are determined as follows:

{fₚ,fₛ,aₚ,aₛ}={300 KHz,400 KHz,3 dB,40 dB}

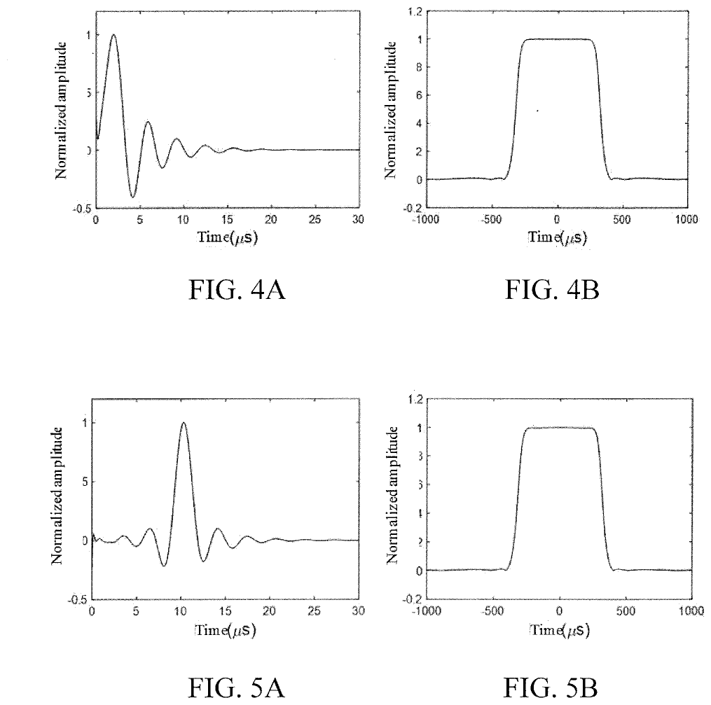

A 7-order Chebyshev II low-pass filter is designed according to the parameters, and the unit pulse response and amplitude-frequency response of the Chebyshev II low-pass filter are shown in FIG. 4. A 7-order all-pass filter is designed for phase compensation. The unit pulse response and amplitude-frequency response of the sampling kernel after compensation are shown in FIG. 5.

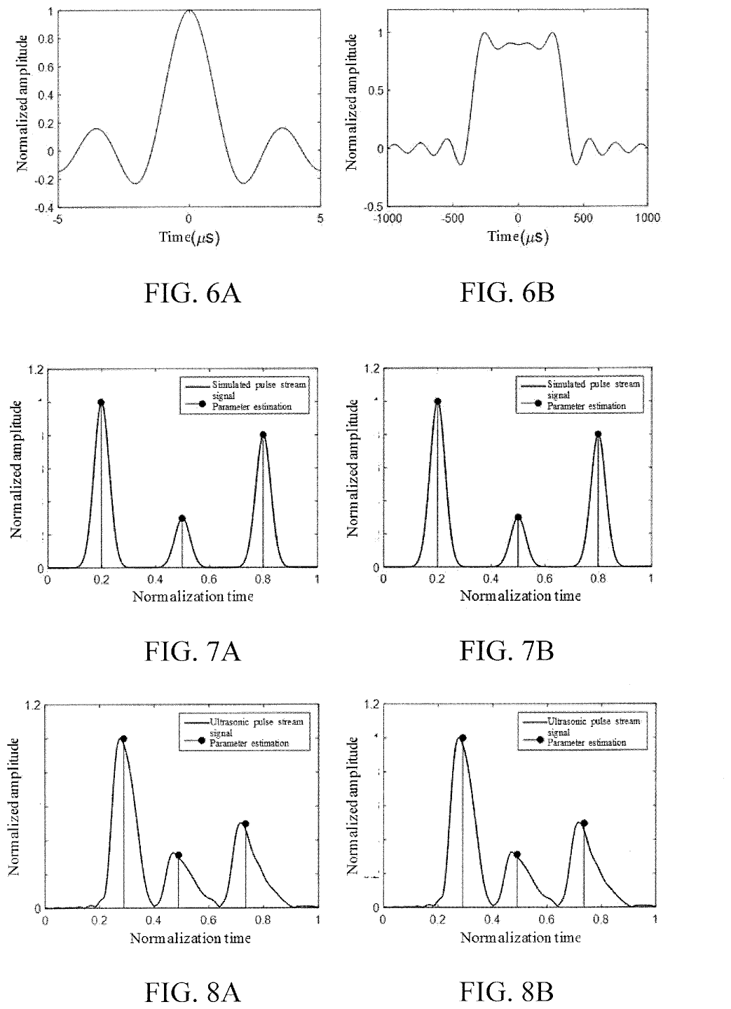

In the experiment, the parameter estimation results obtained with the designed sampling kernel is compared with those obtained with an existing digital SoS sampling kernel, the parameter estimation algorithm uses an annihilating filter method, the unit pulse response and amplitude-frequency response of the SoS sampling kernel are shown in FIG. 6. Sparse sampling is carried out for the pulse stream signal respectively with both sampling kernels described above, and the parameter estimation is carried out by the annihilating filter method. The experimental results are shown in FIG. 7.

It is seen from the experimental results that both sampling kernels can recover the time delay and amplitude information of the original signal accurately.

Hereunder the effect of the hardware circuit of the sampling kernel provided in the present invention will be further described by an actual measurement experiment of ultrasonic signal.

The actually measured effective duration of the ultrasonic pulse stream signal is τ=10 μs, and the number of pulses is L=3. In the experiment, the designed sampling kernel circuit is utilized to receive an actual ultrasonic pulse stream signal and to sparsely sample the output signal and the number of sampling points is 7. At the same time, over-sampling is carried out for the actual ultrasonic pulse stream signal, the digital samples of the pulse stream signal are convoluted with the SoS sampling kernel, and then the sparse data is obtained at equal intervals; the number of sampling points is 7. Parameter estimation is carried out with the sparse data obtained with both sampling kernels respectively. The experimental results are shown in FIG. 8.

It is seen from the experimental results that the sampling kernel provided in the present invention can be implemented easily with the hardware circuit, and the actual reconstruction effect is essentially consistent with a SoS sampling kernel. The sampling kernel provided in the present invention avoids the problems of the existing sparse sampling method in which a signal is obtained by conventional sampling first and then sparse sampling is implemented in a software approach. Instead, the sampling kernel provided in the present invention can obtain sparse data directly with hardware. Therefore, it can be applied in hardware systems for FRI sparse sampling of actual signals to realize sparse sampling of the signals.

The above detailed description is provided only to describe some feasible embodiments of the present invention, and they are not intended to limit the protection scope of the present invention. Any equivalents or modification implemented without departing from the technical spirit of the present invention shall be deemed as falling within the protection scope of the present invention.

1. A FRI sparse sampling kernel function construction method, characterized in that said method comprises the following steps:
Step 1: determining the number and distribution intervals of Fourier series coefficients required for accurately estimating signal parameters from sparsely sampled data, according to the characteristics of the FRI pulse stream signal and the parameters to be estimated subsequently;
Step 2: obtaining amplitude-frequency criteria that must be met by frequency domain response of a sampling kernel, according to the number and the distribution intervals of the Fourier series coefficients required for parameter estimation in the step 1;
Step 3: designing a frequency response function for a Fourier series coefficient screening circuit and determining performance parameters of the frequency response function of the sampling kernel, according to the amplitude-frequency criteria for the sampling kernel in the step 2, wherein, the parameters include: pass-band cut-off frequency, stop-band cut-off frequency, maximum pass-band attenuation coefficient and minimum stop-band attenuation coefficient;
Step 4: utilizing a phase correction module to phase correct the transfer function, and thereby obtaining a corrected transfer function of the sampling kernel, i.e., a final sampling kernel function, in order to improve stability of response of the Fourier series coefficient screening circuit and accuracy of parameter estimation, according to the characteristics of phase nonlinearity of the frequency response function for the Fourier series coefficient screening circuit determined in the step 3.

2. The FRI sparse sampling kernel function construction method according to claim 1, characterized in that, the FRI pulse stream signal in the step 1 is extended to a periodic pulse stream signal by the following expression:
$$x ( t ) = {\sum }_{m ∈ Z} {\sum }_{l = 0}^{L - 1} {a}_{l} h ( t - {t}_{l} - m τ )$$
wherein, tₗ∈[0, τ), aₗ∈C, l=1, . . . , L, τ is the period of signal x(t), L is the number of pulses in a single period, and h(t) is a pulse in a known shape; m is an integer, and Z is the set of integers.

3. The FRI sparse sampling kernel function construction method according to claim 1, characterized in that, the required Fourier series coefficients are determined as
$$X [ \frac{2 π k}{τ} ] ,$$
k∈{−L, . . . , L}, according to the period τ of the FRI pulse stream signal and the number of pulses L in a single period in the step 1, with an annihilating filter parameter estimation method.

4. The FRI sparse sampling kernel function construction method according to claim 3, characterized in that said method further comprises that according to the Fourier series coefficient required for reconstruction in the Step 1, the frequency domain response of the sampling kernel obtained in the Step 2 must satisfy the following amplitude-frequency criteria:
$$\vert S ( f ) \vert = \{ \begin{matrix}0 & f = \frac{k}{τ} , k ∉ K \\ not zero & f = \frac{k}{τ} , k ∈ K \\ arbitrary value & others\end{matrix}$$
wherein, S(f) is the frequency domain response of the sampling kernel, K={−L, . . . , L}.

5. The FRI sparse sampling kernel function construction method according to claim 4, characterized in that, according to the amplitude-frequency criteria for the sampling kernel, the sampling kernel parameters based on the frequency response function for the Fourier series coefficient screening circuit must satisfy the following criteria:
$$\{ \begin{matrix}{f}_{p} \geq \frac{L}{τ} \\ {f}_{s} \leq \frac{L + 1}{τ} \\ \vert S ( f ) \vert \neq 0 , f \leq {f}_{p} \\ \vert S ( f ) \vert = 0 , f \geq {f}_{p}\end{matrix}$$
wherein, fₚ is pass-band cut-off frequency, and fₛ is stop-band cut-off frequency.

6. The FRI sparse sampling kernel function construction method according to claim 5, characterized in that, preferred values of the pass-band cut-off frequency fₚ and the stop-band cut-off frequency fₛ are as follows respectively:
$$\{ \begin{matrix}{f}_{p} = \frac{2 L}{τ} \\ {f}_{s} = \frac{2 L + 1 °}{τ}\end{matrix} .$$

7. The FRI sparse sampling kernel function construction method according to claim 1, characterized in that, maximum pass-band attenuation aₚ and minimum stop-band attenuation aₛ of the sampling kernel are determined according to the requirement for the accuracy of signal reconstruction and the difficulty in physical implementation of the sampling kernel.

8. A FRI sparse sampling kernel function construction circuit, characterized in that said circuit comprises a Fourier series coefficient screening module and a phase correction module connected in series; the Fourier series coefficient screening module is configured to obtain Fourier series coefficients required for parameter estimation when the pulse stream signal passes through; and the phase correction module is configured to compensate the nonlinear phase of the Fourier series coefficient screening module, so that the phase of the Fourier series coefficient screening module in a pass band is approximately linear.

9. The FRI sparse sampling kernel function construction circuit according to claim 8, characterized in that, the Fourier series coefficient screening module uses a Chebyshev II low-pass filter circuit and the phase correction module uses an all-pass filter circuit.

10. The FRI sparse sampling kernel function construction circuit according to claim 8, characterized in that, the Fourier series coefficient screening module, based on a basic active low-pass filter link in a Sallen-key structure, is implemented by three-stage operational amplifier circuits cascade; and the active low-pass filter link is a 7-order link composed of five-stage high-speed operational amplifiers ADA4857 and a resistance-capacitance (RC) network that are connected in cascade; the phase correction module is implemented by an active all-pass filter link which is composed of high-speed operational amplifiers ADA4857 and a resistance-capacitance network.
